(19) United States
(12) Patent Application Publication
(10) Pub. No.: US 2012/0314385 A1
(43) Pub. Date: Dec. 13, 2012

(54) CIRCUIT BOARD AND ELECTRONIC APPARATUS

(75) Inventor: Kazuo Mishima, Kanagawa (JP)

(73) Assignee: SONY CORPORATION, Tokyo (JP)

(21) Appl. No.: 13/483,418

(22) Filed: May 30, 2012

(30) Foreign Application Priority Data
Jun. 7, 2011 (JP) 2011-127687

(51) Int. Cl. H05K 9/00; H05K 5/00

(52) U.S. Cl. 361/752

(57) ABSTRACT

A circuit board includes: a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the patter formation surface to cover part of the plurality of electronic components; and a connector terminal for high frequency signals mounted to the shield case such that it extends in a direction along the pattern formation surface.

### CROSS-REFERENCE TO RELATED APPLICATION

The present application claims priority from Japanese Patent Application No. JP 2011-127687 filed in the Japanese Patent Office on Jun. 7, 2011, the entire content of which is incorporated herein by reference.

### FIELD

The present disclosure relates to the field of techniques associated with circuit boards and electronic apparatus. More specifically, the present disclosure relates to the field of techniques for manufacturing a circuit board suffering from less noise at a low cost by providing the circuit board with a shield case which is connected to a ground pattern in predetermined parts thereof, i.e., grounding parts.

### BACKGROUND

Electronic apparatus such as television receivers and personal computers have circuit boards disposed in a housing thereof. A circuit board includes a base substrate to serve as a base section and a plurality of electronic components mounted on at least either side of the base substrate. For example, a circuit board is formed with various circuits such as a circuit operating for providing outputting images and sounds and a driving circuit operating based on high frequency signals such as an RF (radio frequency) signal.

Circuits on a circuit board as thus described and, more particularly, parts (blocks) on such a circuit board processing high frequency signals are liable to noise (interfering wave). For example, a tuner block having a connector terminal (antenna terminal) is apt to take in noise especially through the connector terminal. When such a block takes in noise, the operation of the block may be adversely affected.

Therefore, a circuit board must have high performance in shielding blocks thereon, in particular, blocks processing high frequency signals from noise to keep such blocks in a proper state of operation by preventing noise from entering them.

In some electronic apparatus according to the related art, a tuner block is provided in a shield case having an opening facing toward a base substrate of a circuit board, and a part of the shield case is formed as an grounding piece connected to a ground pattern to prevent noise from entering the tuner block through a connecter terminal thereof (for example, see JP-A-2006-13279 (Patent Document 1)).

Such a shield case having an opening facing toward a base substrate allows required electronic components contained in the shield case to be mounted on the base substrate unlike a box-shaped shield case having six faces. As a result, there is no need for providing a dedicated tuner board inside the shield case, which allows a circuit board to be manufactured at a lower cost.

### SUMMARY

In the case of a circuit board disclosed in Patent Document 1, a part of a shield case is formed as an elongate grounding piece, and the grounding piece is connected to a ground pattern. Since the grounding piece contacts the ground pattern over a small area, a problem arises in that noise cut-off performance is low.

Under the circumstance, it is desirable to solve the above-described problem or to suppress noise while achieving a reduction in manufacturing cost.

An embodiment of the present disclosure is directed to a circuit board including: a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the patter formation surface to cover part of the plurality of electronic components; and a connector terminal for high frequency signals mounted to the shield case such that it extends in a direction along the pattern formation surface. The shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof. The peripheral wall section is formed by a first wall portion, a second wall portion, a third wall portion, and a fourth wall portion which are provided in the order listed in the circumferential direction of the shield case. The connector terminal is mounted on the first wall portion. At least an edge of the first wall portion on one end thereof is connected to the ground pattern. A part of the inner wall section extending across the connector terminal to be contiguous with the side of the shield case opposite to the edge of the first wall portion is connected to the ground pattern.

In the circuit board, each of the parts of the shield case located opposite to each other across the connector terminal is connected to the ground pattern.

In one embodiment of the present disclosure, the circuit board as described above is preferably configured such that the shield case is formed by bending a sheet-like material having a predetermined shape at least in a part thereof into another predetermined shape, the second wall portion and the fourth wall portion continue to the first wall portion through the inner wall section, and each of the second wall portion and the fourth wall portion is connected to the ground pattern at an edge on one end thereof.

The second wall portion and the fourth wall portion continue to the first wall portion through the inner wall section, and each of the second wall portion and the fourth wall portion is connected to the ground pattern at an edge on one end thereof. As a result, the shield case has regions connected to the ground pattern on both sides thereof when viewed in the direction orthogonal to the direction of connecting a grounding part formed on the first wall portion and a grounding part formed on the inner wall section.

In one embodiment of the present disclosure, the circuit board as described above is preferably configured such that the shield case is formed by bending a sheet-like material having a predetermined shape at least in a part thereof into another predetermined shape, and each of a plurality of different parts of the inner wall section is connected to the ground pattern.

Since each of a plurality of different parts of the inner wall section is connected to the ground pattern, the shield case is connected to the ground pattern in a greater number of locations in the neighborhood of the connector terminal, which provides a greater area of connection.

In one embodiment of the present disclosure, the circuit board as described above is preferably configured such that the shield case is formed by bending a sheet-like material having a predetermined shape at least in a part thereof into another predetermined shape, the peripheral wall section is continuously formed, and the peripheral wall section is connected to the ground pattern at an edge on one end thereof.

The peripheral wall section is continuously formed, and the peripheral wall section is connected to the ground pattern at an edge on one end thereof. Thus, the shield case is connected to the ground pattern over a great area in regions thereof contiguous to the first wall portion on which the connector terminal is mounted.

In one embodiment of the present disclosure, the circuit board as described above is preferably configured such that the inner wall section is formed with a heat transfer hole, and the electronic components are mounted in a position on the base substrate opposite to the inner wall section.

The inner wall section is formed with a heat transfer hole, and the electronic components are mounted in a position on the base substrate opposite to the inner wall section. As a result, heat is transferred to the electronic components mounted in the position opposite to the inner wall section through the heat transfer hole.

Another embodiment of the present disclosure is directed to an electronic apparatus including a circuit board disposed in a housing, the circuit board including: a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the pattern formation surface to cover part of the plurality of electronic components; and a connector terminal for high frequency signals mounted to the shield case such that it extends in a direction along the pattern formation surface. The shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof. The peripheral wall section is formed by a first wall portion, a second wall portion, a third wall portion, and a fourth wall portion which are provided in the order listed in the circumferential direction of the shield case. The connector terminal is mounted on the first wall portion. At least an edge of the first wall portion on one end thereof is connected to the ground pattern. A part of the inner wall section extending across the connector terminal to be contiguous with the side of the shield case opposite to the edge of the first wall portion is connected to the ground pattern.

In the electronic apparatus, each of the parts of the shield case located opposite to each other across the connector terminal is connected to the ground pattern.

The circuit board according to the embodiment of the present disclosure includes a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the patter formation surface to cover part of the plurality of electronic components; and a connector terminal for high frequency signals mounted to the shield case such that it extends in a direction along the pattern formation surface. The shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof. The peripheral wall section is formed by a first wall portion, a second wall portion, a third wall portion, and a fourth wall portion which are provided in the order listed in the circumferential direction of the shield case. The connector terminal is mounted on the first wall portion. At least an edge of the first wall portion on one end thereof is connected to the ground pattern. A part of the inner wall section extending across the connector terminal to be contiguous with the side of the shield case opposite to the edge of the first wall portion is connected to the ground pattern.

Therefore, the shield case is connected to the ground pattern over a great area in the neighborhood of the connector terminal. Further, no tuner board is provided. It is therefore possible to suppress the influence of noise on the connector terminal while achieving a reduction in manufacturing cost.

In one embodiment of the present disclosure, the shield case is formed by bending a sheet-like material having a predetermined shape at least in a part thereof into another predetermined shape. The second wall portion and the fourth wall portion continue to the first wall portion through the inner wall section. Each of the second wall portion and the fourth wall portion is connected to the ground pattern at an edge on one end thereof.

As a result, the shield case has regions connected to the ground pattern on both sides thereof when viewed in the direction orthogonal to the direction of connecting a grounding part formed on the first wall portion and a grounding part formed on the inner wall section. Therefore, the shield case is connected to the ground pattern over a greater area in the neighborhood of the connector terminal, which allows further suppression of the influence of noise on the connector terminal.

In one embodiment of the present disclosure, the shield case is formed by bending a sheet-like material having a predetermined shape at least in a part thereof into another predetermined shape, and each of a plurality of different parts of the inner wall section is connected to the ground pattern.

Therefore, the shield case is connected to the ground pattern over a greater area in the neighborhood of the connector terminal, which allows further suppression of the influence of noise on the connector terminal.

In one embodiment of the present disclosure, the shield case is formed by bending a sheet-like material having a predetermined shape at least in a part thereof into another predetermined shape. The peripheral wall section is continuously formed. The peripheral wall section is connected to the ground pattern at an edge on one end thereof.

Therefore, the shield case is connected to the ground pattern over a greater area in regions thereof contiguous with the first wall portion on which the connector terminal is mounted, which allows further suppression of the influence of noise on the connector terminal.

In one embodiment of the present disclosure, the inner wall section is formed with a heat transfer hole, and the electronic components are mounted in a position on the base substrate opposite to the inner wall section.

Therefore, when the electronic components are bonded to the base substrate using a reflow process, the electronic components are sufficiently heated in the reflow furnace through the heat transfer hole. Thus, the electronic components can be bonded to the base substrate with improved strength and improved reliability.

The electronic apparatus according to the embodiment of the present disclosure includes a circuit board disposed in a housing. The circuit board includes: a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the pattern formation surface to cover part of the plurality of electronic components; and a connector terminal for high frequency signals mounted to the shield case such that it extends in a direction along the pattern formation surface. The shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof. The peripheral wall section is formed by a first wall portion, a second wall portion, a third wall portion, and a fourth wall portion which are provided in the order listed in the circumferential direction of the shield case. The connector terminal is mounted on the first wall portion. At least an edge of the first wall portion on one end thereof is connected to the ground pattern. A part of the inner wall section extending across the connector terminal to be contiguous with the side of the shield case opposite to the edge of the first wall portion is connected to the ground pattern.

Thus, the shield case is connected to the ground pattern over a great area in the neighborhood of the connector terminal. Further, there is no tuner substrate. It is therefore possible to suppress the influence of noise on the connector terminal while achieving a reduction in manufacturing cost.

### BRIEF DESCRIPTION OF THE DRAWINGS

FIG. 1 is a front view of an electronic apparatus according to an embodiment of the present disclosure;

FIG. 2 is a perspective view of a circuit board according to an embodiment of the present disclosure showing one side thereof;

FIG. 3 is a perspective view of the circuit board according to the embodiment showing another side thereof;

FIG. 4 is an enlarged exploded perspective view of a shield case according to the embodiment shown along with connector terminals mounted thereon;

FIG. 5 is an enlarged expanded view of the shield case according to the embodiment shown along with connector terminals mounted thereon;

FIG. 6 is a graph showing results of measurement of the influence of noise on the shield case according to the embodiment and a shield case according to the related art;

FIG. 7 is an enlarged exploded perspective view of a shield case according to a first modification of the embodiment showing the case along with connector terminals mounted thereon;

FIG. 8 is an enlarged expanded view of the shield case according to the first modification showing the case along with connector terminals mounted thereon;

FIG. 9 is an enlarged exploded perspective view of a shield case according to a second modification of the embodiment showing the case along with connector terminals mounted thereon; and

FIG. 10 is an enlarged expanded view of the shield case according to the second modification showing the case along with connector terminals mounted thereon.

### DETAILED DESCRIPTION

An embodiment of a circuit board and an electronic apparatus according to the present disclosure will now be described with reference to the accompanying drawings.

The embodiment described below represents the use of an electronic apparatus according to the present disclosure for a television receiver and the use of a circuit board according to the present disclosure as a circuit board provided in a television receiver.

The application of the present disclosure is not limited to television receivers and circuit boards to be used therein, and the present disclosure may be widely applied to various electronic apparatus including a circuit board having a connector terminal for high frequency signals disposed in a housing and to such circuit boards provided in electronic apparatus. More particularly, the present disclosure may be applied to a wide variety of information processing apparatus and information terminal apparatus other than television receivers such as personal computers, radios, audio recording/reproducing apparatus, image recording/reproducing apparatus, mobile phones, imaging apparatus, and communication apparatus.

### [Configuration of Electronic Apparatus]

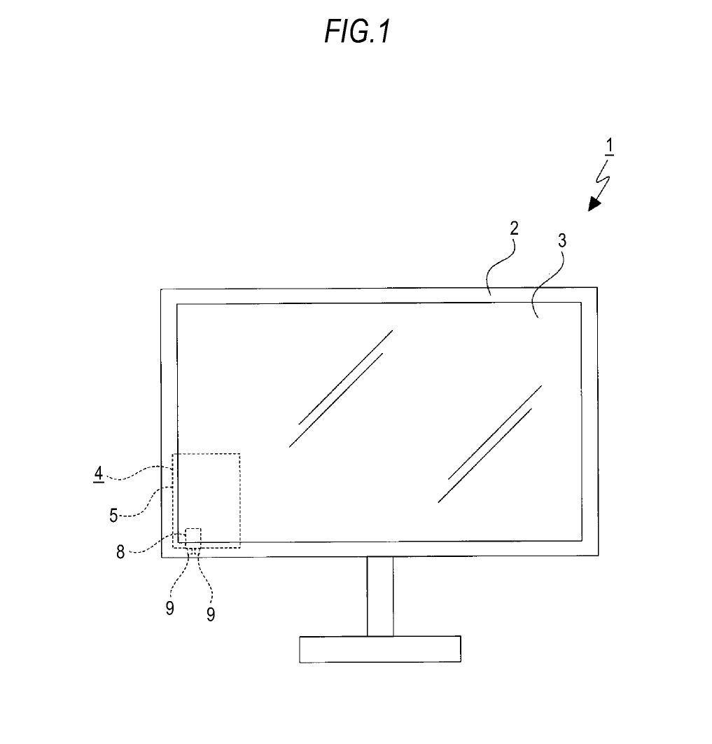

An electronic apparatus (television receiver) 1 includes a housing 2 and various parts disposed in the housing 2 (see FIG. 1). A display 3 for displaying images is disposed in the housing 2. For example, a liquid crystal display, an organic EL (electro-luminescence) display, or a plasma display may be used as the display 3. A circuit board 4 is disposed in the housing 2.

### [Configuration of Circuit Board]

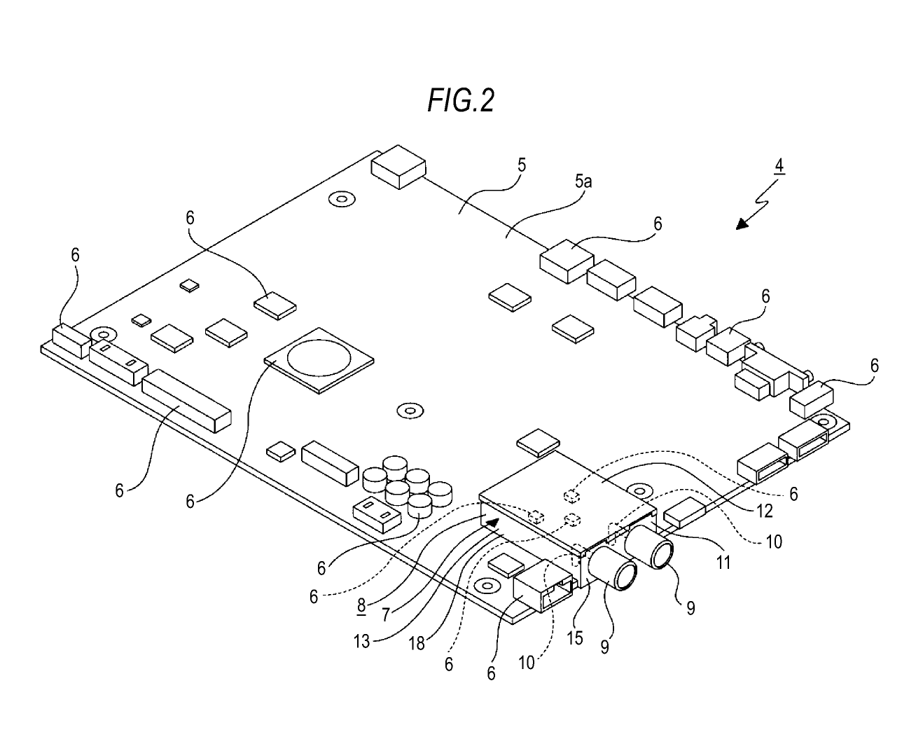

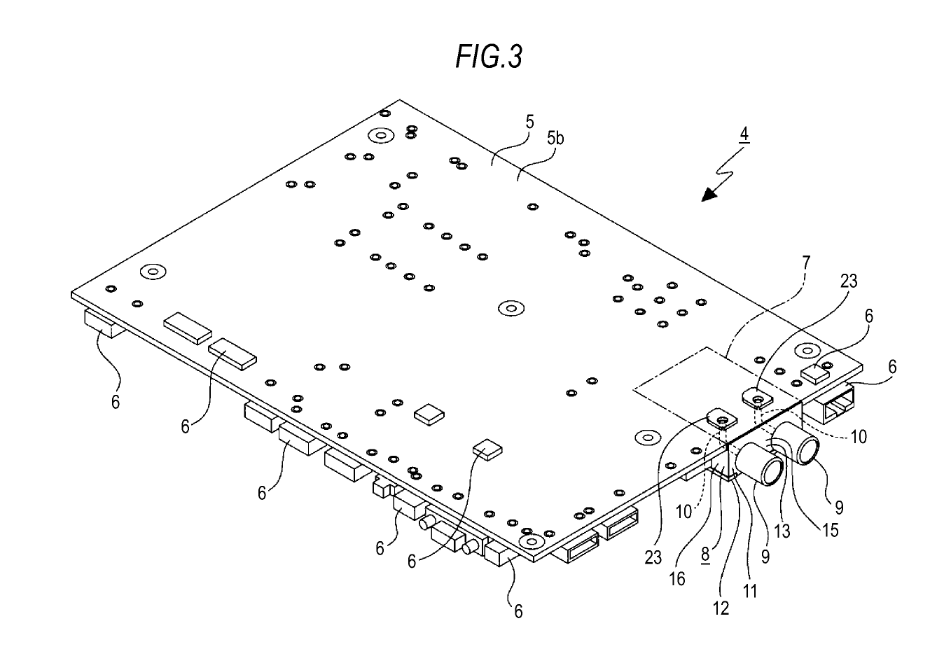

The circuit board 4 includes a base substrate 5 provided as a base section of the board and a plurality of electronic components 6 mounted on each of a surface 5a on one side of the base substrate 5 and a surface 5b on another side of the substrate (see FIGS. 2 and 3).

For example, the base substrate 5 is formed in a rectangular shape, and a predetermined circuit pattern is formed on each of the surface 5a on one side and the surface 5b on the other side. Therefore, both of the surface 5a of the base substrate 5 and the other surface 5b of the substrate constitute a pattern formation surface on which a circuit pattern is formed. Alternatively, only either of the surface 5a and the other surface 5b of the base substrate 5 may constitute a pattern formation surface.

The circuit patterns include a ground pattern for grounding. For example, the base substrate 5 is disposed in such an orientation that the longitudinal direction of the substrate coincides the vertical direction and that the surface 5a and the other surface 5b face frontward and rearward, respectively.

For example, transistors, diodes, photo-couplers, resistors, leads, thermistors, capacitors, filters, and connector terminals are used as the electronic components 6.

The number of electronic components 6 mounted on the surface 5a of the base substrate 5 is greater than the number of components on the other surface 5b.

The circuit board 4 has a plurality of parts or blocks having different functions, and a tuner block 7 is provided at the bottom end of the circuit board 4. The tuner block 7 serves as a tuning device for selecting an electric wave, and an electric wave received by an antenna is input to the tuner block 7. For example, the tuner block 7 includes a high frequency amplification circuit, a mixing circuit, a local oscillation circuit, and a tuning circuit.

The tuner block 7 includes a shield case 8, connector terminals 9, connection terminals 10, and electronic components 6 disposed in the shield case 8.

The shield case 8 is in the form of a rectangular box which has a small thickness and which is open toward the surface 5a of the substrate, and the case is solder-bonded to the surface 5a.

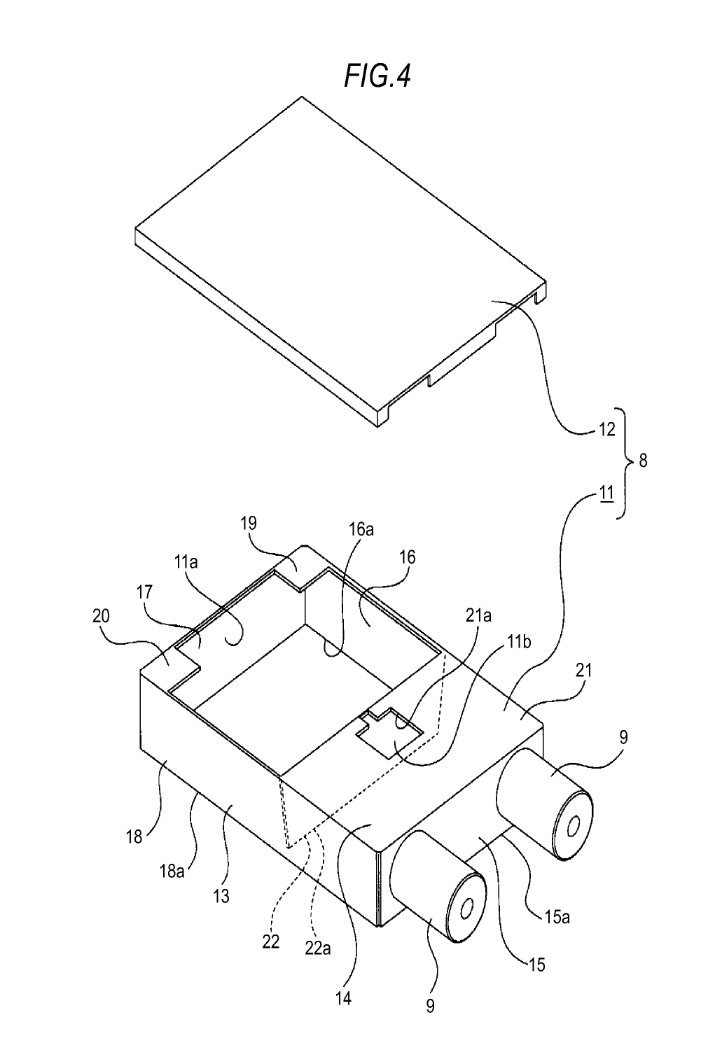

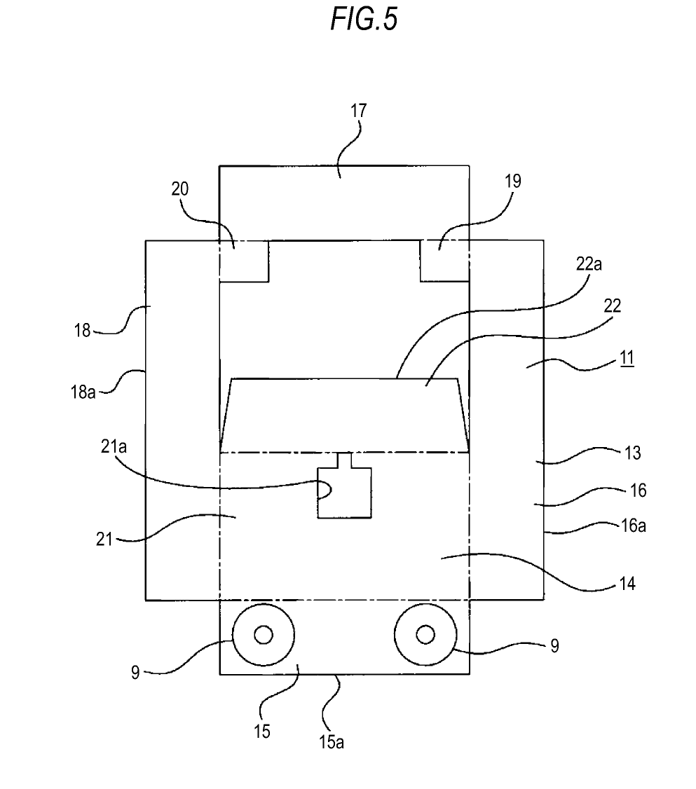

The shield case 8 is provided by combining a main body 11 formed by bending a sheet-like material having a predetermined shape into another predetermined shape and a cover plate 12 covering a front side of the main body 11 (see FIGS. 4 and 5).

The main body 11 has a peripheral wall section 13 formed like a rectangular frame and an inner wall section 14 located inside the peripheral wall section 13.

The peripheral wall section 13 includes a first wall portion 15, a second wall portion 16, a third wall portion 17, and a fourth wall portion 18. The first wall portion 15 is formed in a horizontally elongated substantially rectangular shape and is disposed so as to face upward and downward. Each of the second wall portion 16 and the fourth wall portion 18 is formed in a vertically elongated substantially rectangular shape, and they are disposed apart from each other so as to face leftward and rightward. The third wall portion 17 is formed in a horizontally elongated substantially rectangular shape and is spaced above the first wall portion 15 so as to face upward and downward.

The first wall portion 15 is formed with a pair of mounting holes (not shown) which are spaced from each other in the left-right direction. A rear edge of the first wall portion 15 is formed to serve as a grounding part 15a.

Rear edges of the second wall portion 16 and the fourth wall portion 18 are formed to serve as grounding parts 16a and 18a, respectively.

A top end of the second wall portion 16 and a right end of the third wall portion 17 are connected by a connecting part 19, and a top end of the fourth wall portion 18 and a left end of the third wall portion 17 are connected by a connecting part 20.

The inner wall section 14 includes a connecting wall portion 21 formed with a rectangular outline and a projecting wall portion 22 projecting rearward from a top edge of the connecting wall portion 21. The inner wall section 14 is located to cover substantially the lower half of the space inside the peripheral wall section 13.

A bottom edge of the connecting wall portion 21 is contiguous with a front edge of the first wall portion 15. A right side edge of the wall portion 21 is contiguous with a front edge of the second wall portion 16. A left side edge of the wall portion 21 is contiguous with a front edge of the fourth wall portion 18. A heat transfer hole 21a is formed in an upper part of the connecting wall portion 21, the transfer hole being located in the middle of the wall portion when viewed in the left-right direction of the shield case.

A rear edge of the projecting wall portion 22 is formed as a grounding part 22a.

As described above, the main body 11 is formed by bending a sheet-like material having a predetermined shape into another predetermined shape. Specifically, as shown in the expanded view of FIG. 5, the main body 11 is formed by bending the sheet-like material such that each of the top edge of the first wall portion 15, the left side edge of the second wall portion 16, the bottom edge of the third wall portion 17, the right side edge of the fourth wall portion 18, and the bottom edge of the projecting wall portion 22 points rearward at an angle of 90 deg. When the main body 11 is thus formed, a first space 11a and a second space 11b are formed on top and bottom sides of the projecting wall portion 22 inside the peripheral wall section 13, respectively.

The cover plate 12 is formed in a rectangular shape having substantially the same outline dimensions as the peripheral wall section 13.

When the main body 11 is formed as described above, the cover plate 12 is combined with the main body 11 from the front side thereof, whereby a shield case 8 is formed. The cover plate 12 is combined with the main body 11 by appropriate means such as caulking or welding.

The connector terminals 9 serve as connecting portions to which respective external antenna cables (not shown) are connected. Each of the connector terminals is mounted in a mounting hole provided on the first wall portion at a top end thereof so as to extend in the vertical direction.

The shield case 8 is combined with the base substrate 5 at a bottom end of the surface 5a of the substrate using appropriate means such as soldering (see FIG. 2). At this time, each of the grounding parts 15a, 16a, 18a, and 22a of the shield case 8 is connected to the ground pattern.

The connection terminals 10 are cable conductors through which high frequency signals (RF signals) are passed, and the terminals are bent in the form of the letter “L”. One end (bottom end) of each connection terminal 10 is connected to a terminal portion (not shown) disposed in the respective connector terminal 9, and another end (rear end) of each connection terminal is bonded to the base substrate 5 such that it extends through an insertion hole (not shown) formed on the base substrate 5. That is, the connection terminals 10 are bonded to the base substrate 5 such that the rear ends thereof protrude from the surface 5a's side of the base substrate 5 toward the surface 5b's side of the substrate.

The electronic components 6 which are components forming the tuner block 7 are mounted on the surface 5a of the base substrate 5 in the region inside the shield case 8. Specifically, the electronic components 6 are disposed in each of the first space 11a and the second space 11b formed inside the shield case 8. The electronic components 6 disposed in the first space 11a and the second space 11b are types of components different from each other having different functions. Digital components are disposed in the first space 11a, and the components disposed in the second space 11b are components which are vulnerable to noise (interfering wave) attributable to the digital components disposed in the first space 11a.

As thus described, the electronic components 6 disposed in the second space 11b are components which are vulnerable to noise attributable to the electronic components 6 disposed in the first space 11a.

However, the second space 11b is a space surrounded by various parts of the shield case 8, and the rear edges of the first wall portion 15, the second wall portion 16, the fourth wall portion 18, and the projecting wall portion 22 forming the second space 11b are formed as the respective grounding parts 15a, 16a, 18a, and 22a which are each connected to a ground pattern. It is therefore possible to suppress the influence of noise attributable to the electronic components 6 disposed in the first space 11a on the electronic components 6 disposed in the second space 11b.

As shown in FIG. 3, covers 23 are solder-bonded to the surface 5b of the base substrate 5, and the ends of the connection terminals 10 protruding from the surface 5a's side of the base substrate 5 toward the surface 5b's side of the substrate are covered with the covers 23.

Thus, the covers 23 make it possible to suppress noise which can otherwise enter the connector terminals 9 from the connection terminals 10 and exert an adverse effect.

### [Results of Measurement]

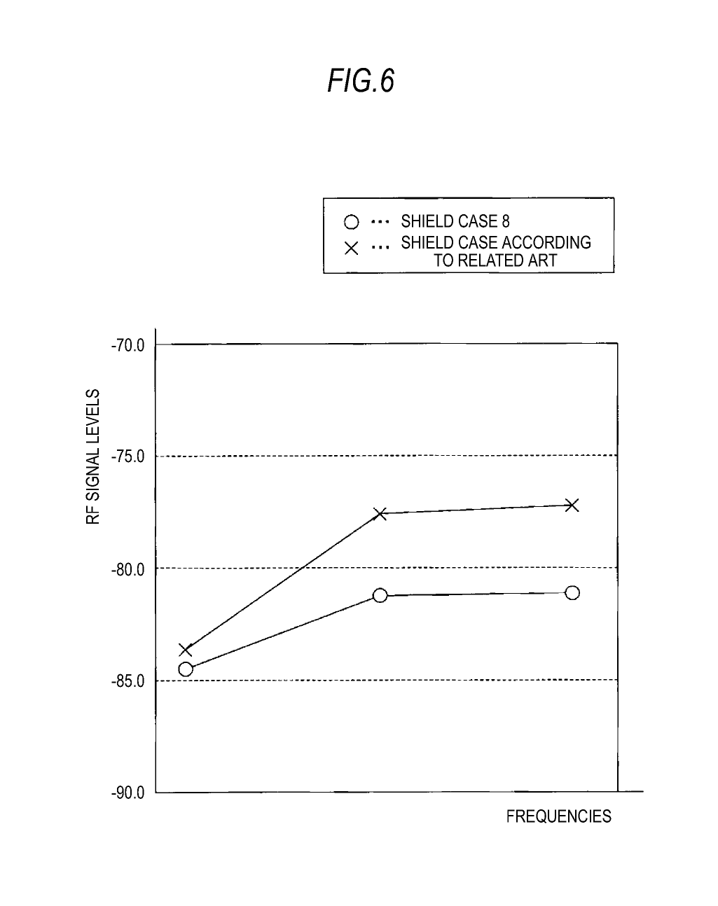

Results of measurement of the influence of noise exerted on the shield case 8 and a shield case according to the related art will now be described (see FIG. 6). In the shield case according to the related art, a grounding part is formed in a region thereof corresponding to the first wall portion described above.

FIG. 6 shows results of measurement carried out on the level of RF signals input to connector terminals (terminals for satellite broadcast) of the shield case 8 and the shield case according to the related art. The horizontal axis of the graph represents frequencies, and the vertical axis represents levels of RF signals.

RF signals input to the connector terminals 9 of the shield case 8 have higher levels compared to signals input to the shield case according to the related art as shown in FIG. 6, and it has been revealed that high sensitivity is achieved according to the embodiment as a result of suppression of the influence of noise.

### [Brief]

As described above, the circuit board 4 has the grounding part 15a which is formed on the first wall portion 15 of the shield case 8 where the connector terminals 9 are provided. The circuit board also has the grounding part 22a formed on the projecting wall portion 22 of the inner wall section 14 which is located opposite to the first wall portion 15 so as to sandwich the connector terminals 9.

Since the shield case 8 on the circuit board 4 is formed in a box-like shape which is open toward the surface 5a, there is no need for providing a tuner board for mounting the connection terminals 10 and the electronic components 6 in the shield case 8, and the connection terminals 10 and the electronic components 6 can be bonded to the base substrate 5 or mounted in a state that is called “chip-on-board”.

The shield case 8 is therefore connected to the ground pattern over a great area in the neighborhood of the connector terminals 9, and there is no tuner board. As a result, it is possible to prevent noise from entering through the connector terminals 9 while achieving a reduction in manufacturing cost.

Further, the main body 11 of the shield case 8 on the circuit board 4 is formed by bending a sheet-like material having a predetermined shape into another predetermined shape. The second wall portion 16 and the fourth wall portion 18 continue to the first wall portion 15 through the inner wall section 14, and the second wall portion 16 and the fourth wall portion 18 are formed with the grounding parts 16a and 18a, respectively.

Therefore, the shield case has regions connected to the ground pattern also on both sides thereof when viewed in the direction orthogonal to the direction of connecting the grounding parts 15a and 22a. The regions increase the area over which the shield case 8 is connected to the ground pattern in the neighborhood of the connector terminals 9, which allows the influence of noise on the connector terminals 9 to be suppressed further.

### [Others]

The electronic components 6 of the circuit board 4, the main body 11 of the shield case 8, and the covers 23 are bonded to the base substrate 5 using what is called a reflow process. For example, solder paste added with flux is applied to predetermined locations on the base substrate 5, and the electronic components 6 and so on are placed on the solder paste. Heating is then performed using a reflow furnace to melt the solder paste. The main body 11 is bonded to the base substrate 5 by the reflow process before the cover plate 12 is bonded.

The electronic components 6 and the main body 11 of the shield case 8 are bonded to the base substrate 5 using a reflow process as thus described. The main body 11 is formed with the heat transfer hole 21a in communication with the second space 11b, and the first space 11a opens frontward.

Therefore, when the electronic components 6 and so on are bonded to the base substrate 5 using a reflow process, the electronic components 6 disposed in the first space 11a and the second space 11b are sufficiently heated in the reflow furnace. Thus, the electronic components 6 can be bonded to the base substrate 5 with improved bonding strength and improved reliability.

### [Modifications of Shield Case]

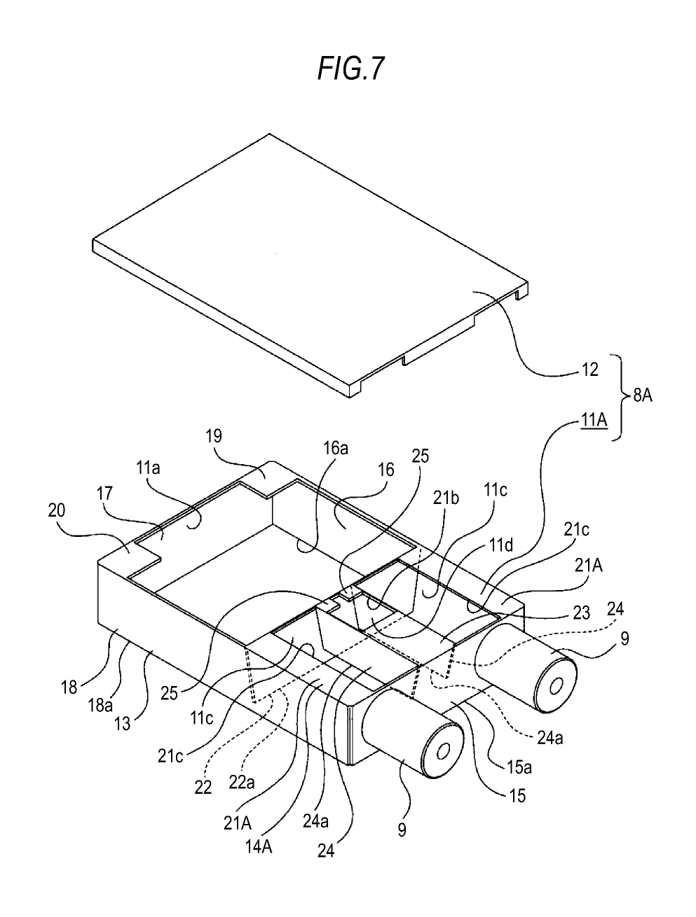

First and second modifications of the shield case will now be described (see FIGS. 7 to 10). A shield case according to the first modification and a shield case according to the second modification are different from the above-described shield case 8 only in some parts of their shapes. Therefore, only differences between shield cases according to the first and second modifications and the shield case 8 will be described in detail, and parts identical between the modifications and the shield case 8 will be indicated by respective identical reference numerals and will not be described.

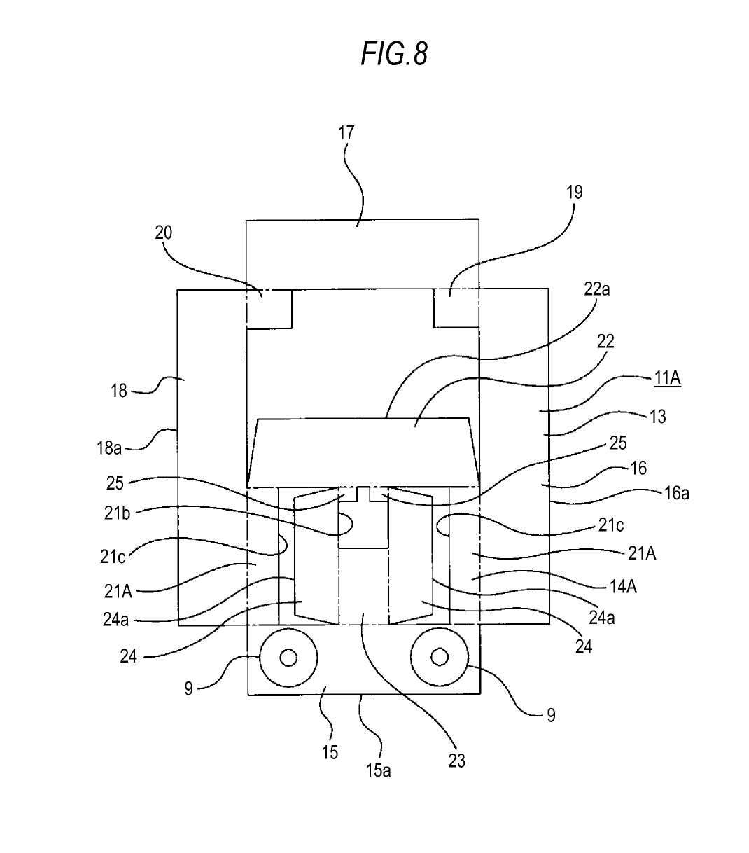

A shield case 8A according to the first modification will now be described (see FIGS. 7 and 8).

The shield case 8A is a combination of a main body 11A which is formed by bending a sheet-like material having a predetermined shape into another predetermined shape and a cover plate 12 which covers a front side of the main body 11A.

The main body 11A includes a peripheral wall section 13 and an inner wall section 14A located inside the peripheral wall section 13.

The inner wall section 14A is formed by connecting wall portions 21A, a central wall portion 23, inner projecting wall portions 24, and a projecting wall portion 22. The inner wall section 14A is located inside the peripheral wall section 13 to occupy substantially the lower half of the area defined by the wall section 13.

The connecting wall portions 21A are formed in a vertically elongated rectangular shape and are disposed apart from each other on the left and right sides of the shield case. Bottom edges of the connecting wall portions 21A are contiguous with a front edges of a first wall portion 15 at left and right ends of the first wall portion. A right side edge of the connecting wall portion 21A located on the right side of the case is contiguous with a front edge of a second wall portion 16. A left side edge of the connecting wall portion 21A located on the left side of the case is contiguous with a front edge of a fourth wall portion 18.

The center wall portion 23 is located between the connecting wall portions 21A and formed in a vertically elongated rectangular shape. A heat transfer hole 21b is formed above the center wall portion 23, and heat transfer holes 21c are formed on the left and right sides of the center wall portion 23.

The inner projecting wall portions 24 project rearward from left and right side edges of the center wall portion 23, respectively. Rear edges of the inner projecting wall portions 24 are formed as respective grounding parts 24a. Top ends of the inner projecting wall portions 24 are connected with the projecting wall portion 22 by respective connecting pieces 25.

The projecting wall portion 22 is not formed with a grounding part 22a unlike the identical portion of the shield case 8.

As described above, the main body 11A is formed by bending a sheet-like material having a predetermined shape into another predetermined shape. Specifically, as shown in the expanded view of FIG. 8, the main body 11A is formed by bending the sheet-like material at an angle of 90° such that each of a top edge of the first wall portion 15, a left side edge of the second wall portion 16, a bottom edge of the third wall portion 17, a right side edge of the fourth wall portion 18, a bottom edge of the projecting wall portion 22, a left side edge of the inner projecting wall portion 24 located on the right side, and a right side edge of the inner projecting wall portion 24 located on the left side points rearward. When the main body 11A is thus formed, a first space 11a is formed above the projecting wall portion 22 inside the peripheral wall section 13, and second spaces 11c and a third space 11d are formed under the projecting wall portion 22. The third space 11d is a space located on the rear side of the center wall portion 23, and the second spaces 11c are spaces located on the left and right sides of the third space 11d.

The heat transfer hole 21b is in communication with the third space 11d, and the heat transfer holes 21c are in communication with the second spaces 11c, respectively.

Electronic components 6 mounted on a base substrate are disposed in each of the first space 11a, the second spaces 11c, and the third space 11d.

The cover plate 12 is combined with the main body 11A formed as described above from the front side thereof, whereby a shield case 8A is formed.

The shield case 8A is combined with the base substrate 5 at a bottom end of a surface 5a of the substrate on one side thereof using appropriate means such as soldering. At this time, each of grounding parts 15a, 16a, 18a, and 24a of the shield case 8A is connected to the ground pattern.

As described above, in the shield case 8A, a grounding part 15a is formed on the first wall portion 15 on which connector terminals 9 are mounted, and grounding parts 24a are formed on respective inner projecting wall portions 24 of the inner wall section 14A, the inner projecting wall portions 24 being contiguous with the side of the shield case opposite to the grounding part 15a with the connector terminals 9 sandwiched therebetween.

The shield case 8A is therefore connected to the ground pattern over a great area in the neighborhood of the connector terminals 9, and there is no tuner board. As a result, it is possible to prevent noise from entering through the connector terminals 9 while achieving a reduction in manufacturing cost.

Further, the main body 11A of the shield case 8A is formed by bending a sheet-like material having a predetermined shape into another predetermined shape. The second wall portion 16 and the fourth wall portion 18 continue to the first wall portion 15 through the inner wall section 14A, and the second wall portion 16 and the fourth wall portion 18 are formed with the grounding parts 16a and 18a, respectively.

Therefore, the shield case has regions connected to the ground pattern also on both sides thereof when viewed in the direction orthogonal to the direction of connecting the grounding parts 15a and 24a. The regions increase the area over which the shield case 8A is connected to the ground pattern in the neighborhood of the connector terminals 9, which allows the influence of noise on the connector terminals 9 to be suppressed further.

In the shield case 8A, each of a plurality of different parts of the inner wall section 14A, i.e., each of the grounding parts 24a of the inner projecting wall portion 24 is connected to the ground pattern.

The parts increase the area over which the shield case 8A is connected to the ground pattern in the neighborhood of the connector terminals 9, which allows the influence of noise on the connector terminals 9 to be suppressed further.

The electronic components 6 and the main body 11A of the shield case 8A are bonded to the base substrate 5 using a reflow process. The main body 11A is formed with the heat transfer holes 21c in communication with the respective second spaces 11c and the heat transfer hole 21b in communication with the third space 11d, and the first space 11a opens frontward.

Therefore, when the electronic components 6 and so on are bonded to the base substrate 5 using a reflow process, the electronic components 6 disposed in the first space 11a, the second spaces 11c, and the third space 11d are sufficiently heated in the reflow furnace. Thus, the electronic components 6 can be bonded to the base substrate 5 with improved bonding strength and improved reliability.

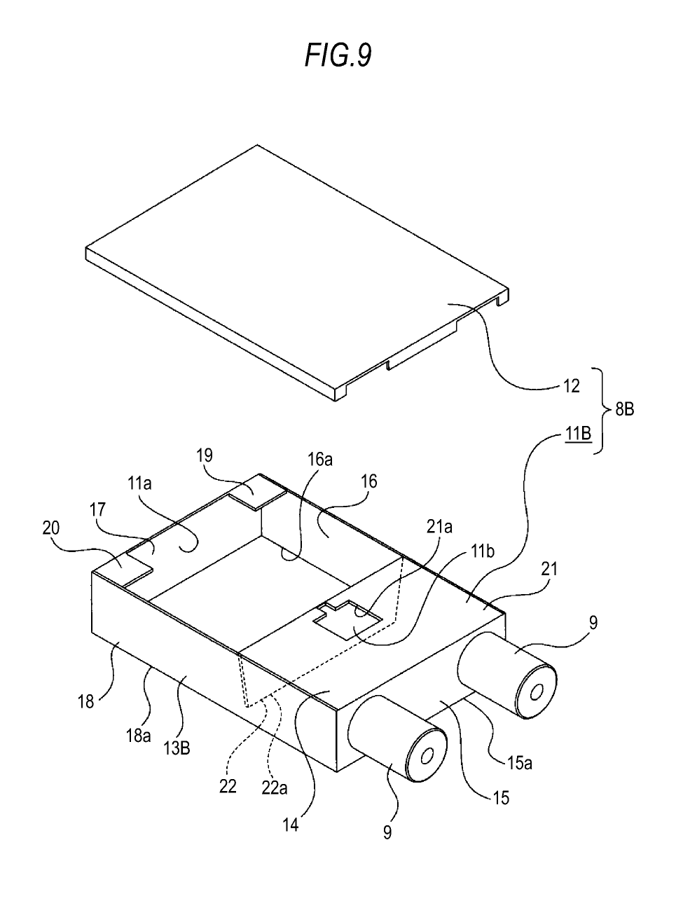

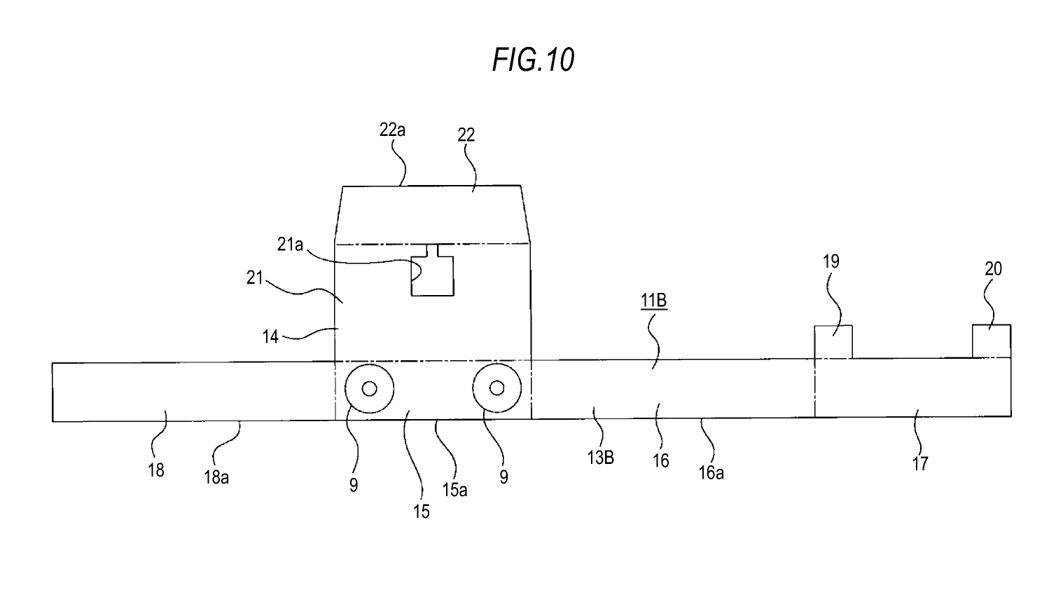

A shield case 8B according to the second modification will now be described (see FIGS. 9 and 10).

The shield case 8B is a combination of a main body 11B which is formed by bending a sheet-like material having a predetermined shape into another predetermined shape and a cover plate 12 which covers a front side of the main body 11B.

The main body 11B includes a peripheral wall section 13B formed in a rectangular frame-like shape and an inner wall section 14B located inside the peripheral wall section 13B.

The peripheral wall section 13B includes a first wall portion 15, a second wall portion 16, a third wall portion 17, and a fourth wall portion 18. A left side edge of the first wall portion 15 is contiguous with a bottom edge of the fourth wall portion 18. A right side edge of the first wall portion 15 is contiguous with a bottom edge of the second wall portion 16. A top edge of the second wall portion 16 is contiguous with a right side edge of the third wall portion 17.

Rear edges of the first wall portion 15, the second wall portion 16, the third wall portion 17, and the fourth wall portion 18 are formed contiguously with each other to serve as grounding parts 15a, 16a, 17a, and 18a, respectively.

A bottom edge of the inner wall section 14 is contiguous with a front edge of the first wall portion 15.

As described above, the main body 11B is formed by bending a sheet-like material having a predetermined shape into another predetermined shape. Specifically, as shown in the expanded view of FIG. 10, the main body 11B is formed by bending the sheet-like material at an angle of 90° such that each of a top edge of the first wall portion 15, a left side edge of the second wall portion 16, a left side edge of the third wall portion 17, a right side edge of the fourth wall portion 18, and a bottom edge of a projecting wall portion 22 points rearward. When the main body 11B is thus formed, a first space 11a and a second space 11b are formed above and under the projecting wall portion 22 inside the peripheral wall section 13B, respectively.

The cover plate 12 is combined with the main body 11B formed as described above from the front side thereof, whereby a shield case 8B is formed.

The shield case 8B is combined with a base substrate 5 at a bottom end of a surface 5a of the substrate on one side thereof using appropriate means such as soldering. At this time, each of grounding parts 15a, 16a, 17a, 18a, and 22a of the shield case 8B is connected to the ground pattern.

As described above, in the shield case 8B, a grounding part 15a is formed on the first wall portion 15 on which connector terminals 9 are mounted, and a grounding part 22a is formed on the projecting wall portion 22 of the inner wall section 14, the projecting wall portions 22 being contiguous with the side of the shield case opposite to the grounding part 15a with the connector terminals 9 sandwiched therebetween.

The shield case 8B is therefore connected the ground pattern over a great area in the neighborhood of the connector terminals 9, and there is no tuner board. As a result, it is possible to prevent noise from entering through the connector terminals 9 while achieving a reduction in manufacturing cost.

Further, the main body 11B of the shield case 8B is formed by bending a sheet-like material having a predetermined shape into another predetermined shape. The peripheral wall section 13B is formed by the first wall portion 15, the second wall portion 16, the third wall portion 17, and the fourth wall portion 18 which are contiguous with each other. Rear edges of the first wall portion 15, the second wall portion 16, the third wall portion 17, and the fourth wall portion 18 are formed to serve as grounding parts 15a, 16a, 17a, and 18a, respectively.

Therefore, the shield case is connected to the ground pattern over a large area in regions thereof contiguous to the first wall portion 15 on which the connector terminals are mounted, which allows the influence of noise on the connector terminals 9 to be suppressed further.

The electronic components 6 and the main body 11B of the shield case 8B are bonded to the base substrate 5 using a reflow process. The main body 11B is formed with a heat transfer hole 21a in communication with the second space lib, and the first space 11a opens frontward.

Therefore, when the electronic components 6 and so on are bonded to the base substrate 5 using a reflow process, the electronic components 6 disposed in the first space 11a and the second spaces 11b are sufficiently heated in the reflow furnace. Thus, the electronic components 6 can be bonded to the base substrate 5 with improved bonding strength and improved reliability.

### [Alternative Modes of Implementation of the Present Disclosure]

The present disclosure may be implemented as the following configurations.

(1) A circuit board including: a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the pattern formation surface to cover part of the plurality of electronic components; and a connector terminal for high frequency signals mounted to the shield case such that it extends in a direction along the pattern formation surface. The shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof. The peripheral wall section is formed by a first wall portion, a second wall portion, a third wall portion, and a fourth wall portion which are provided in the order listed in the circumferential direction of the shield case. The connector terminal is mounted on the first wall portion. At least an edge of the first wall portion on one end thereof is connected to the ground pattern. A part of the inner wall section extending across the connector terminal to be contiguous with the side of the shield case opposite to the edge of the first wall portion is connected to the ground pattern.

(2) The circuit board according to the item (1), wherein the shield case is formed by bending a sheet-like material having a predetermined shape at least in a part thereof into another predetermined shape. The second wall portion and the fourth wall portion continue to the first wall portion through the inner wall section. Each of the second wall portion and the fourth wall portion is connected to the ground pattern at an edge on one end thereof.

(3) The circuit board according to the item (1) or (2), wherein the shield case is formed by bending a sheet-like material having a predetermined shape at least in a part thereof into another predetermined shape, and each of a plurality of different parts of the inner wall section may be connected to the ground pattern.

(4) The circuit board according to the item (1) or (3), wherein the shield case is formed by bending a sheet-like material having a predetermined shape at least in a part thereof into another predetermined shape. The peripheral wall section is continuously formed. The peripheral wall section is connected to the ground pattern at an edge on one end thereof.

(5) The circuit board according to any of the items (1) to (4), wherein the inner wall section is formed with a heat transfer hole, and the electronic components is mounted in a position on the base substrate opposite to the inner wall section.

(6) An electronic apparatus including a circuit board disposed in a housing, the circuit board including: a base substrate having a pattern formation surface at least on either side thereof, the pattern formation surface having a circuit pattern including a ground pattern formed thereon; a plurality of electronic components mounted on the pattern formation surface of the base substrate; a shield case having an opening facing toward the pattern formation surface and mounted on the patter formation surface to cover part of the plurality of electronic components; and a connector terminal for high frequency signals mounted to the shield case such that it extends in a direction along the pattern formation surface. The shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof. The peripheral wall section is formed by a first wall portion, a second wall portion, a third wall portion, and a fourth wall portion which are provided in the order listed in the circumferential direction of the shield case. The connector terminal is mounted on the first wall portion. At least an edge of the first wall portion on one end thereof is connected to the ground pattern. A part of the inner wall section extending across the connector terminal to be contiguous with the side of the shield case opposite to the edge of the first wall portion is connected to the ground pattern.

Any of the specific shapes and configurations of various parts of the above-described embodiment of the present disclosure are presented for merely showing an exemplary mode of implementing the present disclosure, and such examples should not be taken as limiting the technical scope of the present disclosure.

It should be understood by those skilled in the art that various modifications, combinations, sub-combinations and alterations may occur depending on design requirements and other factors insofar as they are within the scope of the appended claims or the equivalents thereof.

What is claimed is:

1. A circuit board comprising:
a base substrate having a pattern formation surface at least on either side thereof, the pattern formation surface having a circuit pattern including a ground pattern formed thereon;
a plurality of electronic components mounted on the pattern formation surface of the base substrate;
a shield case having an opening facing toward the pattern formation surface and mounted on the patter formation surface to cover part of the plurality of electronic components; and
a connector terminal for high frequency signals mounted to the shield case such that it extends in a direction along the pattern formation surface, wherein
the shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof;
the peripheral wall section is formed by a first wall portion, a second wall portion, a third wall portion, and a fourth wall portion which are provided in the order listed in the circumferential direction of the shield case;
the connector terminal is mounted on the first wall portion;
at least an edge of the first wall portion on one end thereof is connected to the ground pattern; and
a part of the inner wall section extending across the connector terminal to be contiguous with the side of the shield case opposite to the edge of the first wall portion is connected to the ground pattern.

2. The circuit board according to claim 1, wherein
the shield case is formed by bending a sheet-like material having a predetermined shape at least in a part thereof into another predetermined shape;
the second wall portion and the fourth wall portion continue to the first wall portion through the inner wall section; and
each of the second wall portion and the fourth wall portion is connected to the ground pattern at an edge on one end thereof.

3. The circuit board according to claim 1, wherein
the shield case is formed by bending a sheet-like material having a predetermined shape at least in a part thereof into another predetermined shape; and
each of a plurality of different parts of the inner wall section is connected to the ground pattern.

4. The circuit board according to claim 1, wherein
the shield case is formed by bending a sheet-like material having a predetermined shape at least in a part thereof into another predetermined shape;
the peripheral wall section is continuously formed; and
the peripheral wall section is connected to the ground pattern at an edge on one end thereof.

5. The circuit board according to claim 1, wherein
the inner wall section is formed with a heat transfer hole; and
the electronic components are mounted in a position on the base substrate opposite to the inner wall section.

6. An electronic apparatus comprising:
a circuit board which is disposed in a housing,
the circuit board including
a base substrate having a pattern formation surface at least on either side thereof, the pattern formation surface having a circuit pattern including a ground pattern formed thereon;
a plurality of electronic components mounted on the pattern formation surface of the base substrate;
a shield case having an opening facing toward the pattern formation surface and mounted on the patter formation surface to cover part of the plurality of electronic components; and
a connector terminal for high frequency signals mounted to the shield case such that it extends in a direction along the pattern formation surface, wherein
the shield case includes a peripheral wall section formed in a frame-like shape and orthogonally bonded to the pattern formation surface at an edge on one end thereof and an inner wall section disposed inside the peripheral wall section and provided contiguously with the peripheral wall section at least in part thereof,
the peripheral wall section is formed by a first wall portion, a second wall portion, a third wall portion, and a fourth wall portion which are provided in the order listed in the circumferential direction of the shield case,
the connector terminal is mounted on the first wall portion,
at least an edge of the first wall portion on one end thereof is connected to the ground pattern, and
a part of the inner wall section extending across the connector terminal to be contiguous with the side of the shield case opposite to the edge of the first wall portion is connected to the ground pattern.
